(19) United States
(12) Patent Application Publication
(10) Pub. No.: US 2026/0164904 A1
(43) Pub. Date: Jun. 11, 2026

(54) DISPLAY DEVICE

(71) Applicant: AUO Corporation, Hsinchu City (TW)

(72) Inventors: Chia-Ting HSIEH, Hsinchu Cit (TW); Tzu-Chin HUANG, Hsinchu City (TW); Chan-Jui LIU, Hsinchu City (TW)

(21) Appl. No.: 19/321,325

(22) Filed: Sep. 8, 2025

(30) Foreign Application Priority Data
Dec. 11, 2024 (TW) 113148257

(51) Int. Cl. H10H 29/856; H10H 29/851

(52) U.S. Cl. CPC H10H 29/856; H10H 29/8514

(57) ABSTRACT

A display device which includes a substrate and a plurality of sub-pixels disposed on the substrate. Each subs-pixel includes a light-emitting component, a light-transmitting structure and a light-transmitting layer. The light-emitting component is disposed on a plane of the substrate and electrically connected to the substrate. The light-transmitting structure is disposed on the plane of the substrate and adjacent to the light-emitting component. The light-transmitting structure includes a side wall facing to the light-emitting component, while a distance between the side wall and the plane of the substrate increases along with the direction away from the light-emitting component. The light-emitting component is used to emit the light ray toward the side wall of the light-transmitting structure. The light-transmitting layer is disposed on the light-transmitting structure and covers the light-emitting component and the side wall of the light-transmitting structure.

### RELATED APPLICATIONS

This application claims priority to Taiwan Application Serial Number 113148257, filed Dec. 11, 2024, which is herein incorporated by reference in its entirety.

### BACKGROUND

### Technical Field

The present disclosure relates to a display device. More particular, the present disclosure relates to the display device which includes solid-state lighting (SSL) components.

### Description of Related Art

The LED panels include an active component substrate and a plurality of LED components disposed on the active component substrate. In general, based on the characteristics of LEDs, the LED panels have advantages, such as power saving, high efficiency, high brightness, and short response time. Thus, the LED panels have a potential to become the mainstream of display panels. However, the light output ratio of LED panels is limited by the light output ratio of LEDs which is difficult to be improved.

### SUMMARY

Accordingly, the disclosure is to provide a display device which is advantage for increasing the light output ratio.

At least one embodiment of the disclosure provides a display device including a substrate and a plurality of sub-pixels. The substrate has a plane, and the plurality of sub-pixels are disposed on the substrate, while each of the plurality of sub-pixels includes a light-emitting component, a light-transmitting structure and a light-transmitting layer. The light-emitting component is disposed on the plane of the substrate and electrically connected to the substrate. The light-transmitting structure is disposed on the plane of the substrate and adjacent to the light-emitting component. The light-transmitting structure includes a first side wall facing to the light-emitting component, and a distance between the first side wall and the plane of the substrate increases along with a direction away from the light-emitting component. The light-emitting component is configured to emit a light ray toward the first side wall of the light-transmitting structure. The light-transmitting layer is disposed on the light-transmitting structure and covers the light-emitting component and the first side wall of the light-transmitting structure.

At least in one embodiment of the disclosure, the total internal reflection of at least a part of the light ray occurs at the first side wall.

At least in one embodiment of the disclosure, the light-transmitting structure extends along with a perimeter of the light-emitting component and surrounds the light-emitting component.

At least in one embodiment of the disclosure, each of the plurality of sub-pixels further includes at least a pair of strip light-transmitting structures disposed on the plane of the substrate and located at two opposite sides of the light-emitting component. The light-emitting component and the light-transmitting structure are located between the strip light-transmitting structures.

At least in one embodiment of the disclosure, a pitch is located between the strip light-transmitting structures and the light-transmitting structure, and the pitch is between 5 μm and 50 μm.

At least in one embodiment of the disclosure, each of the plurality of sub-pixels further includes at least a frame light-transmitting structure disposed on the plane of the substrate. The frame light-transmitting structure extends along with the perimeter of the light-emitting component and surrounds the light-emitting component and the light-transmitting structure.

At least in one embodiment of the disclosure, a pitch is located between the strip light-transmitting structures and the light-transmitting structure, and the pitch is between 5 μm and 50 μm.

At least in one embodiment of the disclosure, the light-transmitting structure further includes a second side wall adjacent to the first side wall and backing onto the light-emitting component. A distance between the second side wall and the plane of the substrate decreases along with the direction away from the light-emitting component.

At least in one embodiment of the disclosure, the light-transmitting structure further includes a second side wall and a top surface. The second side wall backs onto the light-emitting component. A distance between the second side wall and the plane of the substrate decreases along with the direction away from the light-emitting component. The top surface is disposed opposite to the plane of the substrate and adjacent to the first side wall and the second side wall separately.

At least in one embodiment of the disclosure, a reflective index of the light-transmitting layer is larger than a reflective index of the light-transmitting structure.

At least in one embodiment of the disclosure, the display device further includes a pixel separation layer disposed on the plane of the substrate and distributed between the plurality of sub-pixels adjacent to each other.

At least in one embodiment of the disclosure, each of the plurality of sub-pixels further includes a wavelength conversion layer and an adhesive layer. The wavelength conversion layer is disposed on the light-emitting component. The adhesive layer is disposed on the wavelength conversion layer, and the wavelength conversion layer is located between the adhesive layer and the light-transmitting layer.

At least in one embodiment of the disclosure, a reflective index of the light-transmitting structure is n1, and a reflective index of the light-transmitting layer is n2, and a reflective index of the wavelength conversion layer is n3, wherein an angle is between the first side wall and the plane of the substrate, and the angle is an acute angle, wherein the angle α1 meets the inequality: 90°−sin⁻¹(n3/n2)<α1<sin⁻¹(n1/n2)+sin⁻¹(n3/n2).

At least in one embodiment of the disclosure, the angle is larger than 20° and smaller than 70°.

At least in one embodiment of the disclosure, the light-transmitting structure has a height, and a distance between a top surface of the light-emitting component and the plane of the substrate is smaller than the height.

At least in one embodiment of the disclosure, the light-transmitting structure has a width, and the width is between 5 μm and 50 μm.

At least one embodiment of the disclosure provides a display device including a substrate and a plurality of sub-pixels. The substrate has a plane, and the plurality of sub-pixels are disposed on the substrate, while each of the plurality of sub-pixels includes a light-emitting component, a light-transmitting structure and a light-transmitting layer. The light-emitting component is disposed on the plane of the substrate and electrically connected to the substrate. The light-transmitting structure is disposed on the plane of the substrate and adjacent to the light-emitting component. The light-transmitting structure includes a first side wall and two strip regions. The first side wall faces to the light-emitting component, and a distance between the first side wall and the plane of the substrate increases along with a direction away from the light-emitting component. The light-emitting component is configured to emit a light ray toward the first side wall of the light-transmitting structure. The strip regions are located at two opposite sides of the light-emitting component. The light-transmitting layer is disposed on the light-transmitting structure and covers the light-emitting component and the first side wall of the light-transmitting structure.

At least in one embodiment of the disclosure, the light-transmitting structure includes two strip regions located at two opposite sides of the light-emitting component.

At least in one embodiment of the disclosure, the display device further includes at least a pair of strip light-transmitting structures disposed on the plane of the substrate and located at two opposite sides of the light-emitting component. The light-emitting component and the light-transmitting structure are located between the strip light-transmitting structures.

According to the aforementioned embodiments, the light-transmitting structure is disposed on the sub-pixel and adjacent to the light-emitting component. Thus, the light rays emitted by the light-emitting component travel toward the light-transmitting structure, so that a total internal reflection may occur at the first side wall of the light-transmitting structure. Since the distance between the first side wall and the plane of the substrate increases along with the direction away from the light-emitting component, the light ray may be emitted to the direction away from the plane of the substrate after being total-internally reflected by the first side wall. As a result, the light output ratio of sub-pixels increases, thereby improving the efficiency of the display.

### BRIEF DESCRIPTION OF THE DRAWINGS

To illustrate more clearly the aforementioned and the other objects, features, merits, and embodiments of the present disclosure, the description of the accompanying figures are as follows:

FIG. 1 illustrates a top view of a display device in accordance with one embodiment of the present disclosure.

FIG. 2 illustrates a locally top view of the display device in FIG. 1.

FIG. 3 illustrates a cross-sectional view of the display device along with the line A-A of FIG. 2.

FIG. 4 illustrates a locally cross-sectional view of the display device in accordance with another embodiment of the present disclosure.

FIG. 5 illustrates a locally top view of the display device in accordance with another embodiment of the present disclosure.

FIG. 6 illustrates a locally top view of the display device in accordance with another embodiment of the present disclosure.

FIG. 7 illustrates a locally top view of the display device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/−30%, +/−20%, +/−10% or +/−5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

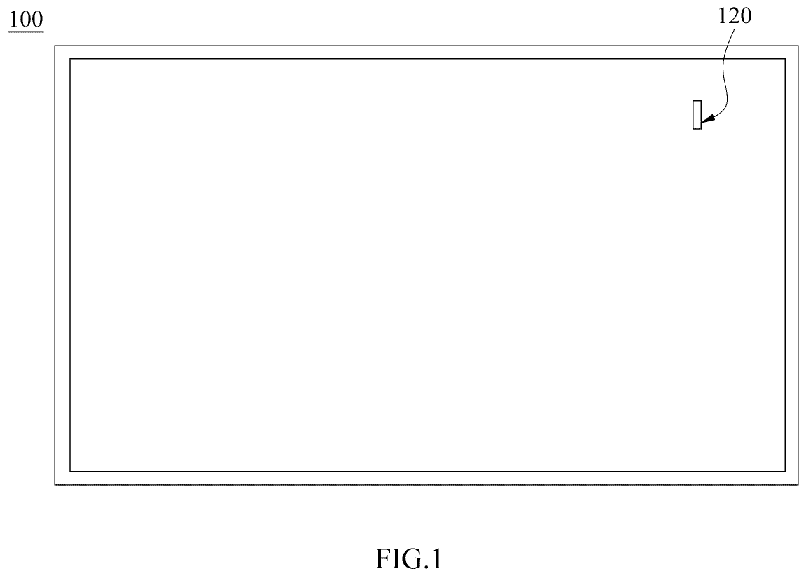

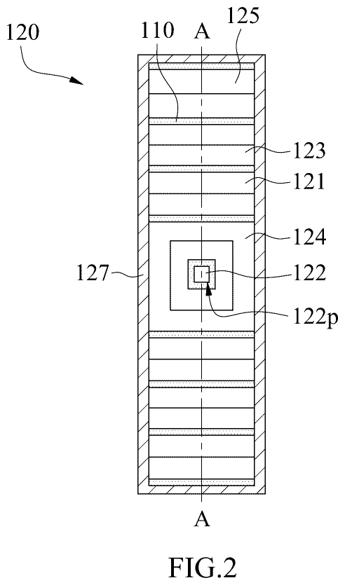

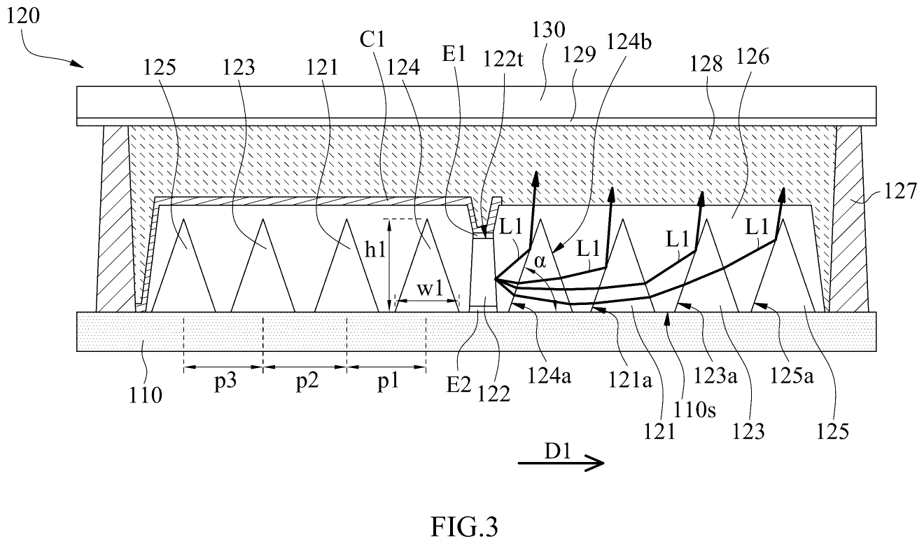

FIG. 1 illustrates a top view of a display device 100 in accordance with one embodiment of the present disclosure. In various embodiments, the display device 100 may be such as a micro LED display, a quantum dot display or similar display devices. FIG. 2 is a top view of the display device 100 in FIG. 1, while the wavelength conversion layer and one of the electrodes (i.e., a wavelength conversion layer 128 and an electrode E1) in sub-pixels are omitted in FIG. 2. FIG. 3 is a cross-sectional view along with the line A-A of FIG. 2. Referring to FIG. 1, FIG. 2 and FIG. 3, the display device 100 includes a substrate 110 and a plurality of sub-pixels 120. The substrate 110 has a plane 110s, and the sub-pixels 120 are disposed on the substrate 110.

Each of the sub-pixels 120 includes at least one light-emitting component 122, a light-transmitting structure 124 and a light-transmitting layer 126. The light-emitting component 122 is disposed on the plane 110s of the substrate 110 and electrically connected to the substrate 110. Specifically, the substrate 110 may be such as a thin film transistor (TFT) substrate or similar electronic component driving substrates. For example, the substrate 110 may be a TFT array substrate or similar pixel array substrates.

In addition, the light-emitting component 122 may be a LED, such as an organic LED (OLED), a micro LED or other similar LEDs. Referring to FIG. 3, the sub-pixel 120 further includes the electrode E1 and an electrode E2, while the light-emitting component 122 is located between the electrode E1 and the electrode E2. The light-emitting component 122 may be electrically connected to a circuit layer C1 through the electrode E1 and be electrically connected to the substrate 110 through the circuit layer C1. Furthermore, the light-emitting component 122 is electrically connected to the substrate 110 through the electrode E2.

The light-emitting component 122 may emit light rays L1 with different wavelengths, respectively. For instance, the light-emitting component 122 may be red light LEDs, green light LEDs and blue light LEDs, while one red light LED, one green light LED and one blue light LED which are adjacent to each other may be defined as one pixel (i.e., a main pixel) of the display device 100. It is worth mentioning, the range of wavelength of the light rays L1 emitted by the light-emitting component 122 is not limited to the embodiment (e.g., at least one of the light-emitting component 122 may be a yellow light LED).

As shown in FIG. 2, the light-transmitting structure 124 is disposed on the plane 110s of the substrate 110 and is spaced apart the light-emitting component 122. It is worth mentioning, in the embodiment, the light-transmitting structure 124 extends along with a perimeter 122p of the light-emitting component 122 and surrounds the light-emitting component 122. In other words, the light-transmitting structure 124 is formed as a frame on the plane 110s of the substrate 110, and the frame encloses the light-emitting component 122. Although the frame is quadrilateral in the embodiment, the shape of the frame is not limited to the embodiment. That is, in other embodiments, the frames may be circular, triangular or in other shapes.

The light-transmitting structure 124 includes a first side wall 124a which faces to the light-emitting component 122, and the distance between the first side wall 124a and the plane 110s of the substrate 110 increases along with a direction D1 away from the light-emitting component 122. In other words, the first side wall 124a of the light-transmitting structure 124 inclines towards the direction D1 away from the light-emitting component 122, while an acute angle α is between the first side wall 124a and the plane 110s of the substrate 110. The light-emitting component 122 is configured to emit the light rays L1 toward the first side wall 124a of the light-transmitting structure 124. Thus, a total internal reflection of at least a part of the light ray L1 occurs at the first side wall 124a, while another part of the light ray L1 enters the light-transmitting structure 124 through the first side wall 124a.

In addition, the light-transmitting structure 124 further includes a second side wall 124b which is adjacent to the first side wall 124a and backs onto the light-emitting component 122. The distance between the second side wall 124b and the plane 110s of the substrate 110 decreases along with the direction D1 away from the light-emitting component 122. In other words, the second side wall 124b of the light-transmitting structure 124 inclines toward the direction approaching the light-emitting component 122 (i.e., toward the reverse of the direction D1). In the embodiment, a part of the light ray L1 which enters the light-transmitting structure 124 through the first side wall 124a exits the light-transmitting structure 124 through the second side wall 124b.

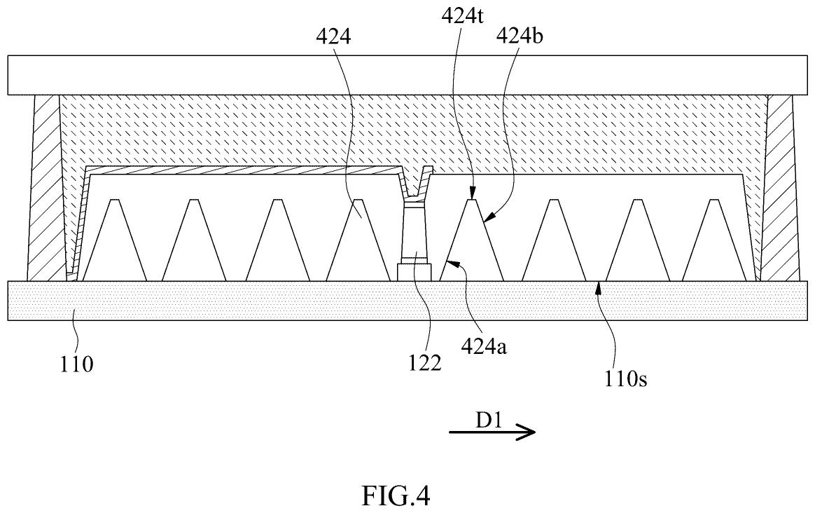

It is worth mentioning, although the cross section of the light-transmitting structure 124 is triangular, the disclosure is not limited to the embodiment. Referring to the embodiment in FIG. 4, the cross section of a light-transmitting structure 424 is trapezoidal. Specifically, the light-transmitting structure 424 includes a first side wall 424a, a second side wall 424b and a top surface 424t. The second side wall 424b backs onto the light-emitting component 122, while the distance between the second side wall 424b and the plane 110s of the substrate 110 decreases along with the direction D1 away from the light-emitting component 122. Furthermore, the top surface 424t of the light-transmitting structure 424 is disposed opposite to the plane 110s of the substrate 110 and is adjacent to the first side wall 424a and the second side wall 424b separately. That is, the second side wall 424b of the light-transmitting structure 424 is not adjacent to the first side wall 424a.

Referring to FIG. 3, each of the sub-pixels 120 further includes at least one pair of strip light-transmitting structure, such as a pair of strip light-transmitting structures 121, a pair of strip light-transmitting structures 123 and a pair of strip light-transmitting structures 125 in FIG. 2 and FIG. 3. The strip light-transmitting structures 121, the strip light-transmitting structures 123 and the strip light-transmitting structures 125 are disposed on the plane 110s of the substrate 110, and each pair of the strip light-transmitting structures (e.g., the strip light-transmitting structures 121) are located at two opposite sides of the light-emitting component 122 separately. The light-emitting component 122 and the light-transmitting structure 124 are located between the strip light-transmitting structures 121. In addition, the light-emitting component 122 and the light-transmitting structure 124 are located between the strip light-transmitting structures 123 (and the strip light-transmitting structures 125). In other words, the strip light-transmitting structures 121, the strip light-transmitting structures 123 and the strip light-transmitting structures 125 are arranged in order along with the direction D1 away from the light-emitting component 122.

The display device 100 further includes a covering layer 130 which is disposed on the sub-pixel 120. Specifically, the covering layer 130 is disposed on the wavelength conversion layer 128 of the sub-pixel 120 and is connected to the wavelength conversion layer 128 through an adhesive layer 129. The sub-pixels 120 are disposed between the substrate 110 and the covering layer 130, and the covering layer 130 may include transparent materials, such as silicone oxide.

In the embodiment, a part of the light ray L1 may transmit through the light-transmitting structure 124, and a total internal reflection occurs at the first side walls 121a of the strip light-transmitting structures 121. A part of the light ray L1 may transmit through the light-transmitting structure 124 and the strip light-transmitting structures 121 in order, and a total internal reflection occurs at the first side walls 123a of the strip light-transmitting structures 123. A part of the light ray L1 may transmit through the light-transmitting structure 124, the strip light-transmitting structures 121 and the strip light-transmitting structures 123, and a total internal reflection occurs at the first side walls 125a of the strip light-transmitting structures 125.

It is worth mentioning, a pitch p1 is located between the strip light-transmitting structure 121 and the light-transmitting structure 124, and the pitch p1 is between 5 μm and 100 μm. Furthermore, a pitch p2 is located between the strip light-transmitting structure 121 and the strip light-transmitting structure 123, while a pitch p3 is located between the strip light-transmitting structure 123 and the strip light-transmitting structure 125. Both of the pitch p2 and the pitch p3 are between 5 μm and 100 μm. Although there are three pairs of the strip light-transmitting structures in the embodiment, the quantity of the strip light-transmitting structure is not limited to the embodiment. In other embodiments, the pair of the strip light-transmitting structures may be other quantity, such as two pairs or four pairs of the strip light-transmitting structures.

In addition, the light-transmitting structure 124 has a height h1, and the distance between a top surface 122t of the light-emitting component 122 and the plane 110s of the substrate 110 is smaller than the height h1. For instance, the height h1 of the light-transmitting structure 124 may be between 3 μm and 30 μm. Furthermore, the light-transmitting structure 124 has a width w1 which is between 5 μm and 50 μm.

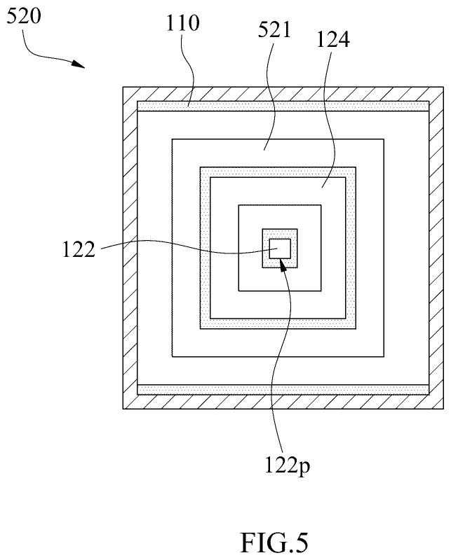

Referring to another embodiment illustrated in FIG. 5, a plurality of sub-pixels 520 are similar to the sub-pixels 120 of the display device 100. The difference between the sub-pixels 520 and the sub-pixels 120 is that each of the sub-pixels 520 further includes at least a frame light-transmitting structure 521. The frame light-transmitting structure 521 is disposed on the plane 110s (referring to FIG. 3) of the substrate 110. The frame light-transmitting structure 521 extends along with the perimeter 122p of the light-emitting component 122 and surrounds the light-emitting component 122 and the light-transmitting structure 124.

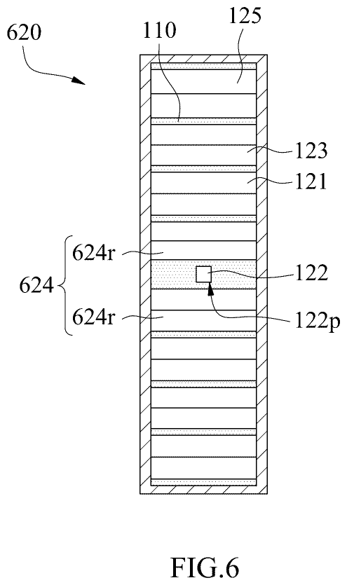

Referring to another embodiment illustrated in FIG. 6, a plurality of sub-pixels 620 are similar to the sub-pixels 120 of the display device 100. The difference between the sub-pixels 620 and the sub-pixels 120 is that a light-transmitting structure 624 of one of the sub-pixels 620 includes two strip regions 624r, and the strip regions 624r are located at two opposite sides of the light-emitting component 122 separately.

Each of the sub-pixels 620 further includes at least one pair of strip light-transmitting structures, for example, the strip light-transmitting structures 121, the strip light-transmitting structures 123 and the strip light-transmitting structures 125. The strip light-transmitting structures 121, the strip light-transmitting structures 123 and the strip light-transmitting structures 125 are disposed on the plane 110s of the substrate 110, while the strip light-transmitting structures in each pair (e.g., the strip light-transmitting structures 121) are disposed on two opposite sides of the light-emitting component 122 separately. The light-emitting component 122 and the light-transmitting structure 624 are located between the strip light-transmitting structures 121. The light-emitting component 122 and the light-transmitting structure 624 are also located between the strip light-transmitting structures 123 (and between the strip light-transmitting structures 125).

Referring to FIG. 3, the light-transmitting layer 126 is disposed on the light-transmitting structure 124 and covers the light-emitting component 122 and the first side wall 124a of the light-transmitting structure 124. It is worth mentioning, in the embodiment, the reflective index of the light-transmitting layer 126 is larger than the reflective index of the light-transmitting structure 124. For instance, the reflective index of the light-transmitting layer 126 may be between 1.5 and 2.0, while the reflective index of the light-transmitting structure 124 may be between 1.1 and 1.5.

The display device 100 further includes a pixel separation layer 127. The pixel separation layer 127 is disposed on the plane 110s of the substrate 110 and distributed between the sub-pixels 120 which are adjacent to each other. Specifically, the pixel separation layer 127 may be encapsulated by metals, such as aluminum, silver, manganese and copper. Thus, the possibility that the light rays L1 emitted by the light-emitting component 122 of the sub-pixels 120 pass through the pixel separation layer 127 may decrease.

Referring to FIG. 3, the sub-pixel 120 may further include the wavelength conversion layer 128 and the adhesive layer 129. The wavelength conversion layer 128 is disposed on the light-emitting component 122, while the adhesive layer 129 is disposed on the wavelength conversion layer 128. The wavelength conversion layer 128 is located between the adhesive layer 129 and the light-transmitting layer 126, and the wavelength conversion layer 128 may include quantum dot materials, fluorescent pigments or other similar wavelength conversion materials. The adhesive layer 129 may be encapsulation adhesives, such as optical clear adhesives (OCA) or similar light-transmitting materials.

The wavelength conversion layer 128 may include wavelength conversion materials with different colors, such as red quantum dot materials or blue fluorescent pigments. Thus, when the light ray L1 which is emitted by the light-emitting component 122 enters the wavelength conversion layer 128, the wavelength conversion materials restrict the part of the light ray L1 that may transmit through the wavelength conversion layer 128 to a specific range of wavelength. For example, the blue fluorescent pigments restrict the light ray L1 that transmits through the wavelength conversion layer 128 to the wavelength of blue light (i.e., between 400 nm and 495 nm), so that the light rays L1 which are not within the wavelength range of blue light may not transmit through the wavelength conversion layer 128.

It is worth mentioning, the reflective index of the light-transmitting structure 124 is n1, the reflective index of the light-transmitting layer 126 is n2, and the reflective index of the wavelength conversion layer 128 is n3. In order to make the total internal reflection of the light rays L1 occurs at the first side wall 124a of the light-transmitting structure 124, the value of an angle α between the first side wall 124a and the plane 110s of the substrate 110 is α1, and the value α1 should meet the inequality: 90°−sin⁻¹(n3/n2)<α1<sin⁻¹(n1/n2)+sin⁻¹(n3/n2) .

For instance, when the reflective index n1 of the light-transmitting structure 124 is between 1.1 and 1.5, the reflective index n2 of the light-transmitting layer 126 is between 1.5 and 2.0, while the reflective index n3 of the wavelength conversion layer 128 is between 1.1 and 2.0. As the result, the value α1 of the angle α is larger than 35° and smaller than 75°.

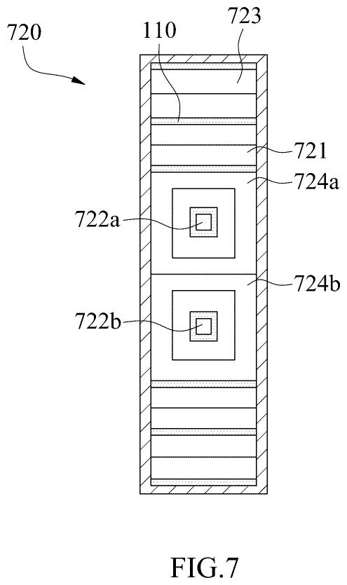

FIG. 7 illustrates another embodiment of the disclosure, and a plurality of sub-pixels 720 are similar to the sub-pixels 120 of the display device 100. The difference between the sub-pixels 720 and the sub-pixels 120 is that each of the sub-pixels 720 includes a light-emitting component 722a, a light-emitting component 722b and a light-transmitting structure 724a and a light-transmitting structure 724b. The light-emitting component 722a and the light-emitting component 722b are both disposed on the plane 110s of the substrate 110. The light-transmitting structure 724a is disposed on the light-emitting component 722a, while the light-transmitting structure 724b is spaced apart the light-emitting component 722b. In the embodiment, the light-transmitting structure 724a and the light-transmitting structure 724b surround the light-emitting component 722a and the light-emitting component 722b respectively.

In addition, each of the sub-pixels 720 includes at least one pair of strip light-transmitting structures, i.e., a strip light-transmitting structure 721 and a strip light-transmitting 723. Each pair of the strip light-transmitting structures (e.g., the strip light-transmitting structure 721) are located at two opposite sides of the light-emitting component 722a and the light-emitting component 722b separately.

In conclusion, by arranging the light-transmitting structure in the sub-pixel and disposing the light-transmitting structure adjacent to the light-emitting component, the light ray emitted by the light-emitting component travels toward the light-transmitting structure, and then a total internal reflection occurs at the first side wall of the light-transmitting structure. Since the distance between the first side wall and the plane of the substrate increases along with the direction away from the light-emitting component, the light ray may be emitted to the direction away from the plane of the substrate after being total-internally reflected by the first side wall. As a result, the light output ratio of sub-pixels increases, thereby improving the efficiency of the display.

Moreover, the strip light-transmitting structures may be disposed on two opposite sides of the light-transmitting structure, or the frame light-transmitting structure may be disposed on the periphery of the light-transmitting structure. Thus, when a part of the light ray from the light-emitting component is not total-internally reflected by the first side wall, the total internal reflection of the light ray may still occur due to the strip light-transmitting structures or the frame light-transmitting structure. Therefore, the light output ratio of sub-pixels increases, thereby increasing the efficiency of the display.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A display device, comprising:
a substrate having a plane;
a plurality of sub-pixels disposed on the substrate, and each of the plurality of sub-pixels comprises:
a light-emitting component disposed on the plane of the substrate and electrically connected to the substrate;
a light-transmitting structure disposed on the plane of the substrate and adjacent to the light-emitting component, wherein the light-transmitting structure comprises a first side wall facing to the light-emitting component, and a distance between the first side wall and the plane of the substrate increases along with a direction away from the light-emitting component, wherein the light-emitting component is configured to emit a light ray toward the first side wall of the light-transmitting structure; and
a light-transmitting layer disposed on the light-transmitting structure and covering the light-emitting component and the first side wall of the light-transmitting structure.

2. The display device of claim 1, wherein a total internal reflection of at least a part of the light ray occurs at the first side wall.

3. The display device of claim 1, wherein the light-transmitting structure extends along with a perimeter of the light-emitting component and surrounds the light-emitting component.

4. The display device of claim 3, wherein each of the plurality of sub-pixels further comprises:
at least a pair of strip light-transmitting structures disposed on the plane of the substrate and located at two opposite sides of the light-emitting component, wherein the light-emitting component and the light-transmitting structure are located between the strip light-transmitting structures.

5. The display device of claim 4, wherein a pitch is located between the strip light-transmitting structures and the light-transmitting structure, and the pitch is between 5 μm and 50 μm.

6. The display device of claim 3, wherein each of the plurality of sub-pixels further comprises:
at least a frame light-transmitting structure disposed on the plane of the substrate, wherein the frame light-transmitting structure extends along with the perimeter of the light-emitting component and surrounds the light-emitting component and the light-transmitting structure.

7. The display device of claim 1, wherein the light-transmitting structure further comprises:
a second side wall adjacent to the first side wall and backing onto the light-emitting component, wherein a distance between the second side wall and the plane of the substrate decreases along with the direction away from the light-emitting component.

8. The display device of claim 1, wherein the light-transmitting structure further comprises:
a second side wall backing onto the light-emitting component, wherein a distance between the second side wall and the plane of the substrate decreases along with the direction away from the light-emitting component; and
a top surface disposed opposite to the plane of the substrate and adjacent to the first side wall and the second side wall separately.

9. The display device of claim 1, wherein a reflective index of the light-transmitting layer is larger than a reflective index of the light-transmitting structure.

10. The display device of claim 1, further comprising:
a pixel separation layer disposed on the plane of the substrate and distributed between the plurality of sub-pixels adjacent to each other.

11. The display device of claim 1, wherein each of the plurality of sub-pixels further comprises:
a wavelength conversion layer disposed on the light-emitting component; and
an adhesive layer disposed on the wavelength conversion layer, wherein the wavelength conversion layer is located between the adhesive layer and the light-transmitting layer.

12. The display device of claim 11, wherein a reflective index of the light-transmitting structure is n1, and a reflective index of the light-transmitting layer is n2, and a reflective index of the wavelength conversion layer is n3, wherein an angle is between the first side wall and the plane of the substrate, and the angle is an acute angle, wherein the angle α1 meets the inequality: 90°−sin⁻¹(n3/n2)<α1<sin⁻¹(n1/n2)+sin⁻¹(n3/n2).

13. The display device of claim 12, wherein the angle is larger than 20° and smaller than 70°.

14. The display device of claim 1, wherein the light-transmitting structure has a height, and a distance between a top surface of the light-emitting component and the plane of the substrate is smaller than the height.

15. The display device of claim 1, wherein the light-transmitting structure has a width, and the width is between 5 μm and 50 μm.

16. A display device, comprising:
a substrate having a plane;
a plurality of sub-pixels disposed on the substrate, and each of the plurality of sub-pixels comprises:
a light-emitting component disposed on the plane of the substrate and electrically connected to the substrate;
a light-transmitting structure disposed on the plane of the substrate and adjacent to the light-emitting component, wherein the light-transmitting structure comprises:
a first side wall facing to the light-emitting component, and a distance between the first side wall and the plane of the substrate increases along with a direction away from the light-emitting component, wherein the light-emitting component is configured to emit a light ray toward the first side wall of the light-transmitting structure; and
two strip regions located at two opposite sides of the light-emitting component; and
a light-transmitting layer disposed on the light-transmitting structure and covering the light-emitting component and the first side wall of the light-transmitting structure.

17. The display device of claim 16, further comprising:
at least a pair of strip light-transmitting structures disposed on the plane of the substrate and located at two opposite sides of the light-emitting component, wherein the light-emitting component and the light-transmitting structure are located between the strip light-transmitting structures.

18. The display device of claim 17, wherein a pitch is located between the strip light-transmitting structures and the light-transmitting structure, and the pitch is between 5 μm and 50 μm.
